(19) United States
(12) Patent Application Publication
(10) Pub. No.: US 2024/0111216 A1
(43) Pub. Date: Apr. 4, 2024

(54) PROCESS FOR DEPOSITION OF AN OUTER LAYER, REFLECTIVE OPTICAL ELEMENT FOR THE EUV WAVELENGTH RANGE AND EUV LITHOGRAPHY SYSTEM

(71) Applicant: Carl Zeiss SMT GmbH, Oberkochen (DE)

(72) Inventors: Dirk EHM, Beckingen (DE); Stefan SCHMIDT, Mettlach (DE); Alfredo MAMELI, Eindhoven (NL); Fred ROOZEBOOM, Eindhoven (NL)

(21) Appl. No.: 18/541,693

(22) Filed: Dec. 15, 2023

Related U.S. Application Data
(63) Continuation of application No. PCT/EP2022/062628, filed on May 10, 2022.

(30) Foreign Application Priority Data
Jun. 16, 2021 (DE) 10 2021 206 168.0

(51) Int. Cl. G03F 7/00; C23C 16/40; C23C 16/455; G02B 5/08

(52) U.S. Cl. CPC G03F 7/702; C23C 16/40; C23C 16/405; C23C 16/45527; C23C 16/4554; C23C 16/45555; C23C 16/45563; G02B 5/0891; G02B 5/10

(57) ABSTRACT

A method of depositing an outer layer (35) on a surface (36) of a reflective optical element (30) for the EUV wavelength range, wherein the depositing is effected in at least one macro cycle (37). The macro cycle (37) includes: at least partly depositing the outer layer (35) with an atomic layer deposition (ALD) process in at least one ALD cycle and partly back-etching the outer layer (35). Also disclosed is a reflective optical element (30) for the extreme ultraviolet (EUV) wavelength range which includes a surface (36) having an outer layer (35), wherein the outer layer (35) is deposited by the above-described method, and to an EUV lithography system having at least one such reflective optical element (30).

### CROSS-REFERENCE TO RELATED APPLICATION

This is a Continuation of International Application PCT/EP2022/062628, which has an international filing date of May 10, 2022, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2021 206 168.0 filed on Jun. 16, 2021.

### FIELD OF THE INVENTION

The invention relates to a method of depositing an outer layer on a surface of a reflective optical element for the EUV wavelength range. The invention also relates to a reflective optical element for the EUV wavelength range, having a surface having an outer layer deposited by the method, and to an EUV lithography system comprising at least one such reflective optical element.

### BACKGROUND

Microstructured or nanostructured components for microelectronics or microsystem technology are produced by optical lithography using optical arrangements in the form of projection exposure apparatuses. Such projection exposure apparatuses include an illumination system for illuminating a photomask (reticle) with electromagnetic radiation in a narrow spectral range around an operating wavelength. These apparatuses also include a projection optics system for projecting a structure of the reticle onto a radiation-sensitive layer of a wafer using the radiation.

In order to achieve the smallest possible structure width for the semiconductor components to be produced, state-of-the-art projection exposure apparatuses, also known as EUV lithography apparatuses, are designed for an operating wavelength in the extreme ultraviolet (EUV) wavelength range, i.e. within a range from about 5 nm to about 30 nm. Since wavelengths in this range are strongly absorbed by just about all materials, it is typically not possible to use transmissive optical elements. Use of reflective optical elements is required. Such optical elements that reflect EUV radiation may, for example, be mirrors, reflective monochromators, collimators or photomasks. Since EUV radiation is also strongly absorbed by air molecules, the beam path of the EUV radiation is arranged within a vacuum chamber.

Optical elements that reflect EUV radiation can also be used in other optical arrangements (EUV lithography systems) that are used in connection with EUV lithography. Examples of these are metrology systems for examining exposed wafers or wafers that are to be exposed, for examining reticles, and for examining further components of EUV lithography apparatuses, such as mirrors.

In operation of the EUV lithography apparatuses or EUV lithography systems, a residual gas that remains in the vacuum chamber contains hydrocarbons. One source of the hydrocarbons is outgassing from components disposed within the vacuum chamber. These components may, for example, be sensors, cables, the mask or the photoresist of the wafer to be structured. A further source of the hydrocarbons may be vapors from the vacuum pump oil that diffuse into the vacuum chamber. The EUV radiation then results in dissociation of the hydrocarbons, which leads to growth of carbon contaminations on the optical surfaces of the reflective optical elements.

In addition to the carbon contaminations, there may also be oxidation of the optical surfaces. The oxidation is caused mainly by free oxygen radicals that are generated by the action of the EUV radiation on water molecules or oxygen molecules. It is also possible for other contaminating substances, for example tin or silicon, to be deposited on the optical surfaces. For cleaning of such contaminations from the optical surfaces, the use of reactive hydrogen has been proposed; cf., for example, WO 2008/034582 A2.

The reactive hydrogen, however, results in an etching attack on exposed, generally uncoated surfaces of materials or of components in optical arrangements for EUV lithography. As a result, etching products are formed, which are converted to the gas phase and released in the vacuum environment. In particular, some elements form volatile hydrides in the presence of hydrogen ions and/or hydrogen radicals. Examples of such elements include tin, zinc, phosphorus, silicon, lead and fluorine. It is generally impossible to completely avoid the positioning of components within the vacuum environment that contain at least one of these elements. The etching products can subsequently be deposited at the surfaces of the reflective optical elements, especially in the optically utilized regions. These deposits reduce the cumulative reflectance of the optical arrangement, lower throughput and increase costs.

WO 2019025162 A1 proposes protecting the material of the main body of an optical element (or optionally the material of a functional coating applied to the main body) in at least one surface region outside the optically utilized surface region against an etching attack and hence against partial material removal by a hydrogen plasma using at least one shield.

US 2007/0125964 A1 states that at least a portion of a cleaning device designed to provide a flow of hydrogen radicals may include a material with a coefficient of surface recombination for hydrogen radicals of not more than 0.02. DE 10 2015 203 160 A1 discloses an optical arrangement for EUV lithography that has an opening channel having an inner wall on which a coating is formed, which contains a material having a hydrogen recombination coefficient of 0.08 or higher for reduction of the level of ingress of activated hydrogen.

DE 10 2015 215 014 A1 describes an EUV projection exposure apparatus comprising a multiplicity of components which at least partly comprise a layer of a precious metal, for example of Rh, Ru, Ir, Pd, Pt. The minimum layer thickness of the layer is chosen such that hydrogen ions and/or hydrogen radicals cannot penetrate through the layer.

The reactive hydrogen can also result in blister formation and even in detachment of the reflective coating of optical elements. A suspected mechanism is the inward diffusion of reactive (atomic) hydrogen into the reflective coating and the recombination of the reactive hydrogen that has diffused in to give molecular hydrogen. In order to solve this problem, US 2019/0171108 A1 proposes disposing a functional layer between the reflective coating and the substrate of the reflective optical element, which reduces the concentration of hydrogen on the side of the substrate facing the reflective coating at least by a factor of 2.

US 2019/0339428 A1 describes a mirror having a reflection layer and a barrier layer system. The barrier layer system is disposed between the reflection layer and the mirror substrate. The barrier layer system reduces the penetration of hydrogen atoms to the mirror substrate by at least a factor of 10 compared to an analogous construction without the barrier layer system.

DE 102020212869.3 describes a method of forming a hydrogen protection layer that can withstand high mechanical stresses, especially in the case of elongation of the substrate at the surface of which the hydrogen protection layer is formed.

A method of providing a dynamic protective layer on a mirror for the EUV wavelength range by which the mirror is protected from an etching attack by ions that form in the EUV wavelength range as a result of the irradiation is also disclosed in EP 1 522 895 B1.

WO 2019/007927 A1 describes a method of at least partly removing a contamination layer from an optical surface of an EUV radiation-reflecting optical element through an atomic layer etching process that can be conducted as a spatial atomic layer etching process.

A method of atomic layer processing of an optical surface of an optical element designed for reflection of EUV radiation is also described in EP 20183384.5. An atomic layer etching process is conducted therein, in order to remove contaminants from the curved optical surface. The atomic layer processing may include an atomic layer deposition process in order to deposit material on the optical surface.

EP 1 364 231 B1 describes a self-cleaning reflective optical element having an outer metal layer that protects the reflective surface of the optical element from oxidation and transmits more than 90% of the EUV radiation. The outer metal layer is a ruthenium layer. It is possible to provide an intermediate metal layer made from chromium, molybdenum or titanium.

The use of a ruthenium layer on a reflective coating of photomasks for the EUV wavelength range is also described in the article “Ruthenium capping layer preservation for 100X clean through pH driven effects” by D. Dattilo et al., Proc. SPIE 9635, Photomask Technology 2015, 96351B. The reflective coating is a layer stack of silicon layers and molybdenum layers. The uppermost layer of the layer stack is a silicon layer. The ruthenium layer serves to protect the silicon from oxidation. The article states that, in the cleaning of such photomasks with a chemical cleaning solution, there can be diffusion of oxygen through the ruthenium layer and oxidation of the silicon beneath the ruthenium layer. Possible consequences are damage to and detachment of the ruthenium layer (cf. also FIG. 3 in the article cited).

DE 10 2017 213 172 A1 describes a method of applying an outer layer on a reflective coating of an optical element for reflection of EUV radiation by atomic layer deposition (ALD), preferably by spatial atomic layer deposition. In one variant, the applying of the outer layer is preceded by applying of at least one protective layer to the reflective coating that may include at least one precious metal, e.g. ruthenium. The outer layer, which may, for example, be an oxidic outer layer, is intended to enable a reduction in the deposition of contaminations on the reflective optical element.

Atomic layer deposition is a class of deposition methods that feature two or more cyclically conducted self-terminating surface reactions. Typically, an ALD cycle comprises two surface reactions: a first component reaction with a precursor, for example a metal precursor, and then a second component reaction with a coreactant, for example water. In the case of conventional ALD methods that are conducted in a reaction chamber, the component reactions are interspersed by purging with an inert gas, such that there is no simultaneous presence of precursor and coreactant in the reaction chamber at any time. In spatial atomic layer deposition, on the other hand, the component reactions proceed in different volume regions. For performance of the component reactions, the substrate to be coated is moved relative to these volume regions. In general, a multitude of ALD cycles is conducted. Characteristic features of ALD methods are excellent layer thickness control and high conformity of the layers thus deposited.

The use of atomic layer deposition for deposition of thin layers on optical elements has been discussed many times in the prior art. For example, WO 2004/095086 A2 describes the deposition of conformal layers on microoptical elements through atomic layer deposition and related methods. WO 2013/113537 A2 also describes atomic layer deposition as a conformal coating process for deposition of the layers of a multilayer stack of a coating of an optical element that reflects EUV radiation. US 2016/0086681 A1, moreover, discloses the production of Fresnel zone plates using atomic layer deposition. Specific gas injectors for injection of gas into a process chamber of an apparatus for atomic layer deposition are also described in U.S. Pat. No. 9,410,248 B2. Designs for spatial atomic layer deposition can be found, for example, in the article “Spatial atomic layer deposition: A route towards further industrialization of atomic layer deposition” by P. Poodt et al., J. Vac. Sci. Technol. A 30, 010802-1 (2012), and in U.S. Pat. Nos. 4,058,430, 7,413,982 B2 and WO 2010/024671 A1.

A typical problem with outer layers on reflective optical elements for the EUV wavelength range is the loss of reflectivity caused by the outer layers. In the case of projection exposure apparatuses for the EUV wavelength range, this loss of reflectivity leads directly to a lower throughput and consequently to higher costs.

### SUMMARY

It was accordingly an object of the invention to provide a method of depositing an outer layer on a reflective optical element for the EUV wavelength range, which effectively protects the reflective optical element and simultaneously leads to only a small loss of reflectivity.

According to one formulation of the invention, this and other objects are achieved in a first aspect by a method of depositing an outer layer on a surface of a reflective optical element for the EUV wavelength range, wherein the depositing is effected in at least one macro cycle comprising: at least partly depositing the outer layer through an atomic layer deposition (ALD) process in at least one ALD cycle and partly back-etching the outer layer.

The reflective optical element for the EUV wavelength range is, for example, a mirror, for example the collector mirror of a projection exposure apparatus, or a photomask. For reflection of radiation in the EUV wavelength range, the reflective optical element may have a reflective coating applied to a substrate. The reflective coating may include, for example, a layer stack of silicon layers and molybdenum layers. The reflection of the EUV radiation in this case is based on interference effects. Alternatively, the reflective coating may serve to reflect EUV radiation on grazing incidence.

A macro cycle refers here to the two successively executed method steps of the above-described method, i.e. the at least partial deposition by atomic layer deposition in a first step and the subsequent partial back-etching in a second step. The atomic layer deposition may also be plasma-assisted.

The outer layer is deposited in one or more macro cycles in which the deposited material of the outer layer is partly back-etched. This procedure affords an outer layer which is simultaneously continuous and comparatively thin. Since the outer layer is continuous, damage to the reflective optical element, for example the reflective coating in the form of the layer stack disposed beneath the outer layer, is effectively suppressed. Unwanted degradation effects are greatly suppressed. The result is that the need for premature and costly cleaning or exchange of the reflective optical element is obviated. As a result of the low final thickness of the outer layer, reflectivity losses are at the same time low. The final thickness in the context of this application is understood to mean the thickness of the outer layer after the outer layer has been deposited in at least one macro cycle, i.e. the thickness after conclusion of the method.

In the simplest case, the outer layer is deposited by conducting just one macro cycle. First of all, the outer layer is deposited by atomic layer deposition, with the thickness of the initially deposited layer being greater than the final thickness of the outer layer. Subsequently, the outer layer is back-etched to the final thickness. As a result, a smoother, more continuous thin outer layer is achieved than if the back-etching is omitted and the outer layer is deposited in the final thickness by atomic layer deposition from the outset.

Alternatively, it is possible to conduct a plurality of macro cycles. In the ALD step of the first macro cycle, growth nuclei are first formed in this case, and proceeding from that a few islands. These are partly back-etched in the second step of the first macro cycle. During the ALD step of the second macro cycle, randomly distributed new growth nuclei are then formed. At the same time, the islands that remained after the back-etching grow again. This description is correspondingly applicable to the further macro cycles. This procedure results in very much more uniform layer growth overall. A continuous outer layer is formed even in the case of comparatively low layer thicknesses, typically even in the case of layer thicknesses of less than 2 nm.

Deposition in two or more macro cycles is typically preferable over deposition in just one macro cycle, since, in the latter case, a continuous outer layer at the surface of the reflective optical element is not formed in all cases in the ALD step, even when the outer layer grown on first in the ALD step is comparatively thick. Under some circumstances, small holes may remain in the surface, which may grow further as a result of the back-etching.

For the at least partial deposition, it is possible to use either thermal or plasma-assisted atomic layer deposition processes. Accordingly, the coreactant(s) may be thermal coreactants or coreactants in plasma form. It is also possible for atomic layer deposition in an ALD reactor to use the gas injectors described in U.S. Pat. No. 9,410,248 B2, for example, in order to inject gas into a process chamber. The partial back-etching may also be plasma-assisted and/or thermal.

One advantage of atomic layer deposition compared to conventional deposition methods such as methods of chemical gas phase deposition (CVD) and physical gas phase deposition (PVD) lies in the comparatively low process temperature. While temperatures of up to 500° C. are obtained in the case of CVD and PVD methods, atomic layer deposition can often be effected even at room temperature. The use of atomic layer deposition can consequently avoid thermal damage to the reflective optical element. Moreover, atomic layer deposition is of much better suitability for production of thin, continuous and defect-free layers. By contrast with conventional deposition methods, atomic layer deposition, because of its self-terminating character and successive growth in ALD cycles, also leads to smoothing of the surface since the different growth fronts merge in the course of deposition. Details of this can be found, for example, in the article “Spatial ALD Challenges and Opportunities in Advanced Integrated Circuit Manufacturing” by D. O'Meara, PRiME 2020, Paper G02-1655; see page 13 in particular.

In one variant of this method, a final thickness of the outer layer after the conclusion of the method is less than 4 nm, preferably less than 2 nm, more preferably between 2 nm and 1 nm.

In a further variant of this method, the surface of the reflective optical element has a protective layer on which the outer layer is deposited, where the protective layer consists at least partly of a metal, preferably of a precious metal. The protective layer typically has a greater thickness than the outer layer and is generally deposited not by atomic layer deposition but, for example, by a method of gas phase deposition, especially by sputtering. In principle, the protective layer may alternatively be deposited by atomic layer deposition. The precious metal may, for example, be rhodium, ruthenium, palladium or zirconium. Because the outer layer is continuous, damage to the outer layer itself, to the protective layer and to the reflective coating, especially through diffusion of O₂ and H₂, is suppressed or reduced.

In a further variant of this method, the number of macro cycles is 2 or more, preferably 5 or more, more preferably 10 or more. As described further up, the repeated back-etching of the outer layer even in the case of low layer thicknesses can produce a continuous outer layer. The final thickness of the outer layer is a product of the number of macro cycles, the number of ALD cycles per macro cycle, the growth per ALD cycle and the layer thickness removed in the back-etching in each macro cycle, in particular the number of back-etching steps per macro cycle. A given final thickness of the outer layer can thus typically be achieved by multiple different combinations of the parameters mentioned.

In a further variant of this method, the number of ALD cycles per macro cycle is between 1 and 100, preferably between 10 and 100.

In a further variant of this method, the outer layer consists at least partly of at least one oxide. It has been found that an outer layer consisting at least partly of an oxide distinctly reduces the deposition of contaminations, especially of hydrides formed by as a result of hydrogen-induced outgassing, and permits simpler removal of the contaminations. However, oxidic outer layers also entail challenges. Especially in the case of the deposition of an oxidic outer layer on a metallic protective layer, it is difficult to achieve a fully continuous outer layer since the surface energies of the metal and of the oxide are typically at great variance from one another. As a result of these different surface energies, what is typically observed is called Stranski-Krastanov (island) growth. In idealized layer-by-layer growth, by contrast, individual islands formed from growth nuclei grow at first, gradually merge, and ultimately form a continuous, gapless layer of relatively high thickness. As a result, specifically for the deposition of oxidic outer layers on metallic protective layers, the method of the invention is particularly advantageous.

In one development of this variant, the at least one oxide is selected from the group comprising: SiO₂, TiOₓ and ZrO₂. TiOₓ refers here to the different titanium oxides. Detailed hereinafter are precursors suitable for the different oxides: Silicon precursors used for the deposition of SiO₂ may, for example, be aminosilanes, such as bis(diethylamino)silane (CAS 27804-64-4) or bis(tert-butylamino)silane (CAS 186598-40-3) or tris(dimethylamino)silane (CAS 15112-89-7), or chlorosilanes, such as SiCl₄ or SiH₂Cl₂. For the deposition of TiOₓ, it is possible to use, for example, alkoxy-based titanium precursors, such as titanium(IV) ethoxide (CAS 3087-36-3) or titanium(IV) isopropoxide (CAS 546-68-9), or chlorine-based titanium precursors, such as TiCl₄. Zirconium precursors used for the deposition of ZrO₂ may, for example, be amino compounds, such as tetrakis(ethylmethylamino)zirconium (CAS 175923-04-3), or amidinates, for example tetrakis(N,N′-dimethylacetamidinate)zirconium. Oxidizing coreactants used in all cases may, for example, be O₂ in the form of an O₂ plasma, ozone, H₂O or H₂O₂.

In a further variant of this method, the back-etching is conducted with a dry etching process, preferably with a reactive ion etching process and/or with an atomic layer etching process (ALE). Analogously to its counterpart, atomic layer deposition, atomic layer etching describes etching processes in which two or more cyclically conducted self-terminating surface reactions are conducted. Back-etching can alternatively be effected with a reactive ion etching process or with a plasma-assisted dry etching process.

In a further variant of this method, the at least partial deposition through the atomic layer deposition process is effected in at least one ALD region, and the partial back-etching in at least one etching region spatially separated from the at least one ALD region.

The at least one ALD region and the at least one etching region are each at least one volume region in a spatially separate arrangement, i.e. spaced apart from one another. In addition, an inert gas stream between the volume regions that forms a gas curtain may be used for spatial separation. The inert gas may, for example, be Ar or N₂. The precursor and the coreactant in the ALD region may also be spatially separated from one another by a gas curtain, for example an inert gas stream.

The at least one ALD region and the at least one etching region are additionally preferably isolated from the surrounding atmosphere, for example likewise with an inert gas stream. Gases in the surrounding atmosphere that have a potential adverse effect on the deposition, for example O₂ and CO₂, thus do not get into the ALD region or into the etching region.

In the case of multiple ALD regions and/or multiple etching regions, these are also spatially separated from one another. The at least partial deposition using atomic layer deposition and the partial back-etching are effected with a relative movement between the ALD region and the etching region on the one hand and the reflective optical element on the other hand, as a result of which at least subregions of the surface of the reflective optical element to be coated are exposed successively to the at least one ALD region and the at least one etching region. A pressure differential may exist between the at least one ALD region and the at least one etching region, for example when the back-etching is effected with reactive ion etching. The method may also be conducted with a reactor having multiple reaction chambers, in which case at least one of the reaction chambers serves as at least one ALD region and at least one further reaction chamber as at least one etching region. In order to be able to conduct the atomic layer deposition and the partial back-etching successively, the reflective optical element may be moved between the reaction chambers. For reactive (deep) ion etching, such reactors were discussed in the article “Cyclic etch/passivation-deposition as an all-spatial concept towards high-rate room temperature Atomic Layer Etching” by F. Roozeboom et al., ECS J. Solid State Sc. Technol., 4, N5067 (2015); see also U.S. Pat. No. 9,761,458. In the method of reactive (deep) ion etching described therein, the conventional passivation step is replaced by the depositing of a passivation layer by atomic layer deposition.

In one development of the variant described above, the back-etching is conducted with a spatial atomic layer etching process. In a spatial atomic layer etching process, the atomic layer etching is effected in at least two spatially separate etching regions. One of the self-terminating component reactions proceeds here in each of the etching regions.

In a further variant of this method, the atomic layer deposition process is conducted as a spatial atomic layer deposition process. In a spatial atomic layer deposition process, the atomic layer deposition is effected in at least two spatially separate ALD regions. The first component reaction, i.e. the reaction with the precursor, takes place in at least one of the ALD regions; the second component reaction, i.e. the reaction with the coreactant, takes place in at least one other ALD region.

Advantages of the spatially separate ALD regions and etching regions, especially of the spatial atomic layer processing, i.e. of the use of a spatial atomic layer etching process and/or of a spatial atomic layer deposition process, lie in the high throughput achieved thereby, the ease of scalability, and the high deposition rates and/or etch rates. Spatial atomic layer processing can be effected at atmospheric pressure and permits particularly low process temperatures, which enables avoidance of thermal damage to the reflective optical element. Some other etching methods can also be conducted at atmospheric pressure. In the case of plasma-assisted deposition, process temperatures can be reduced further. In the case of partial back-etching, a plasma can optionally accelerate the etching reactions.

Processing at atmospheric pressure is particularly advantageous since reflective optical elements for the EUV wavelength range are typically relatively large. This makes it difficult to achieve processing under high-vacuum conditions or low-vacuum conditions, as prevail in conventional dry etching methods, including in conventional variants of reactive ion etching and of atomic layer etching.

In one development of this variant, the deposition is effected using a processing head having a processing surface and feed channels through which process media and inert gas are fed to the processing surface, and drain channels with which reaction products, process media and inert gas are drained from the processing surface, wherein the ALD regions and the at least one etching region are provided spatially separately along the processing surface with the inert gas.

Both the spatial atomic layer deposition and the partial back-etching, for example the spatial atomic layer etching, are conducted in this case with a single combined apparatus. The process media are one or more precursors, the coreactant(s) and/or one or more etching gases. The etching gas(es) may, for example, be CF₄, SF₆, NF₃, CHCl₃, Cl₂ or a mixture of these gases or a mixture of one or more of these gases with O₂. The etching gases may be used for plasma-assisted and/or thermal etching. The precursors are typically provided in gaseous form—optionally in heated form—or as plasma. A suitable inert gas is, for example, Ar or N₂. The reaction products are compounds that form as volatile by-products in the atomic layer deposition or in the partial back-etching. The relative movement between the ALD regions or etching regions and the reflective optical element is reduced to a relative movement between the processing head and the reflective optical element. The feed channels and drain channels are in a parallel arrangement, for example. Alternatively, the feed channels and drain channels may also be in a circular or radial arrangement. In this case, the relative movement between the processing head and the reflective optical element is a rotary movement.

The processing head is designed and the process parameters are chosen such that the individual process steps and component reactions proceed separately from one another. In particular, for spatial separation between the individual ALD regions and between the ALD regions and the at least one etching region, inert gas is fed in and removed again. The distance between the processing surface of the processing head and the surface to be coated and the distances between the feed channels and drain channels are chosen here such that, given a suitable choice of the gas flow, i.e. of the amount of gas flowing per unit time, of all process media and of the inert gas, as a result of the relative movement between the processing head and the reflective optical element, the surface of the reflective optical element to be coated comes into contact separately with the individual process media. In particular, there is no mixing of the different process media and hence reaction of the process media in the gas phase.

In the spatial atomic layer deposition of SiO₂, TiOₓ or ZrO₂, the period during which each subregion of the surface to be coated of the reflective optical element is in contact with an ALD region (also referred to as exposure time) is typically between 100 ms and 500 ms. In the spatial atomic layer deposition of SiO₂, the flow rate of an inert gas stream (for example of an Ar gas stream) that serves as carrier gas for the precursor and flows through a bubbler is preferably between 50 sccm and 500 sccm. In the case of spatial atomic layer deposition of TiOₓ or ZrO₂, the flow rate of the inert gas stream is preferably between 50 sccm and 700 sccm. Moreover, in these cases, the bubbler via which the precursor is fed in can be heated to increase the vapor pressure of the precursor.

In one development of this variant, the partial back-etching is effected by using a plasma source based on a dielectric barrier discharge. Preferably, in this case, a mixture of CF₄ and N₂ or a mixture of CF₄, O₂ and N₂ serves as process medium for the back-etching, which typically takes place at atmospheric pressure. Only free radicals contribute to the etching reactions. As a result, during the back-etching, there is no occurrence of damage by ions and especially no ion implantation since no ions are present. The flow rate of the CF₄ gas stream is preferably between 100 sccm and 500 sccm, the flow rate of the overall gas stream preferably between 5 slm and 10 slm. The proportion by volume of O₂ is preferably between 5% and 20%. The AC voltage applied is preferably between 100 V and 170 V, where the frequency of the AC voltage is preferably between 50 kHz and 100 kHz.

In a further variant of this method, the surface of the reflective optical element is curved and the processing surface of the processing head has a shape matched to the curved surface of the reflective optical element. The shape of the processing surface preferably corresponds to the shape of the surface of the reflective optical element. During atomic layer deposition and partial back-etching, a distance between the processing surface and the curved surface of the reflective optical element in this case is typically between 20 μm and 100 μm.

In a further variant of this method, the outer layer is deposited on a subregion, especially on a damaged subregion, of the surface of the reflective optical element, especially of a collector mirror of an EUV lithography system. In the damaged subregions, the outer layer has been fully or partly removed. Prior to the deposition of the outer layer, the damaged subregions may be identified by a suitable metrology method, for example by an EUV radiometry method.

A further aspect of the invention relates to a reflective optical element for the EUV wavelength range which has a surface having an outer layer, wherein the outer layer has been deposited by the method described above or one of its variants.

A further aspect of the invention relates to an EUV lithography system comprising at least one reflective optical element as described above.

Further features and advantages of the invention will be apparent from the description of working examples of the invention that follows, with reference to the figures of the drawing, which show details associated with the invention, and from the claims. The individual features can be implemented individually in their own right or collectively in any combination in a variant of the invention.

### BRIEF DESCRIPTION OF THE DRAWINGS

Working examples are shown in the schematic drawing and are explained in the description which follows. The figures show:

FIG. 1 a schematic diagram of a projection exposure apparatus for EUV projection lithography in meridional section,

FIG. 2 a schematic diagram of a cross section through the uppermost layers of a reflective optical element for the EUV wavelength range, comprising an outer layer that has been deposited in one or more macro cycles,

FIG. 3 a schematic diagram of the deposition of an outer layer on a surface of a reflective optical element for the EUV wavelength range in a macro cycle,

FIG. 4 a schematic diagram of the deposition of an outer layer on a surface of a reflective optical element for the EUV wavelength range in two or more macro cycles,

FIG. 5 a schematic diagram of a processing head for deposition of an outer layer onto a planar surface of a reflective optical element for the EUV wavelength range, and

FIG. 6 a schematic diagram of a processing head for deposition of an outer layer on a curved surface of a reflective optical element for the EUV wavelength range.

### DETAILED DESCRIPTION

In the description of the drawings that follows, identical reference numerals are used for components that are the same or analogous, or have the same or analogous function.

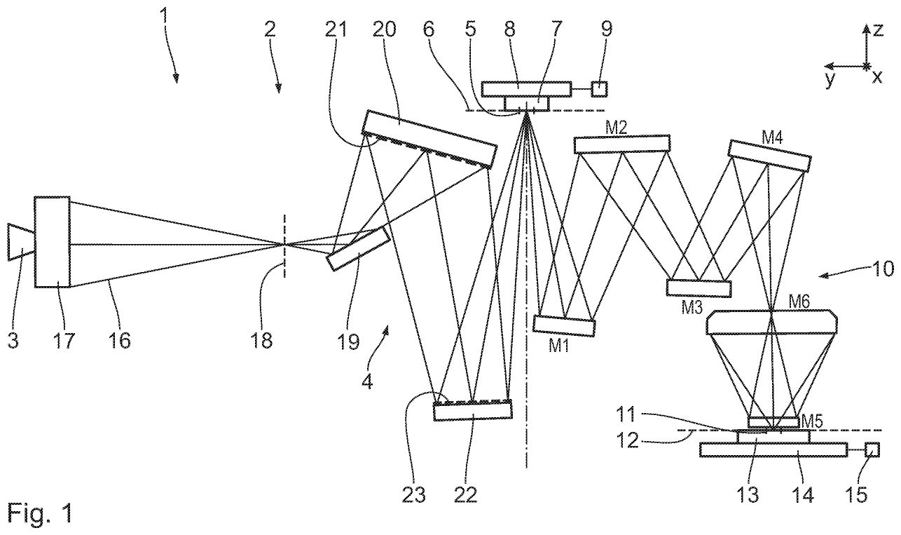

There follows an illustrative description, with reference to FIG. 1, of the predominant constituents of an EUV lithography system in the form of a projection exposure apparatus 1 for microlithography. The description of the basic construction of the projection exposure apparatus 1 and of the constituents thereof should not be regarded here as having a limiting effect.

One design of an illumination system 2 of the projection exposure apparatus 1, in addition to a light or radiation source 3, has an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 disposed in the object field 5 is illuminated. The reticle 7 is held by a reticle holder 8. The reticle holder 8 is displaceable, in particular in a scanning direction, using a reticle displacement drive 9.

By way of explanation, FIG. 1 shows a Cartesian xyz coordinate system. x direction runs perpendicularly into the plane of the drawing. y direction runs horizontally, and z direction runs vertically. Scanning direction runs in y direction in FIG. 1. z direction runs perpendicularly to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 disposed in the region of the image field 11 in the image plane 12. The wafer 13 is held by a wafer holder 14. The wafer holder 14 is displaceable, in particular in y direction, using a wafer displacement drive 15. The displacement firstly of the reticle 7 using the reticle displacement drive 9 and secondly of the wafer 13 using the wafer displacement drive 15 may be mutually synchronized.

The radiation source 3 is an EUV radiation source. The radiation source 3 emits, in particular, EUV radiation 16, which is also referred to below as used radiation, illumination radiation or illumination light. In particular, the used radiation has a wavelength in the range between 5 nm and 30 nm. The radiation source 3 may be a plasma source, for example an LPP source (Laser Produced Plasma) or a GDPP source (Gas Discharge Produced Plasma). It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

The illumination radiation 16 propagates through an intermediate focus in an intermediate focal plane 18 downstream of the collector mirror 17. The intermediate focal plane 18 may constitute a separation between a radiation source module, comprising the radiation source 3 and the collector mirror 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. As an alternative or in addition, the deflection mirror 19 may be designed as a spectral filter that separates a used light wavelength of the illumination radiation 16 from extraneous light of a wavelength deviating therefrom. The first facet mirror 20 comprises a multiplicity of individual first facets 21, which are also referred to below as field facets. FIG. 1 depicts only some of said facets 21 by way of example. In the beam path of the illumination optical unit 4, a second facet mirror 22 is disposed downstream of the first facet mirror 20. The second facet mirror 22 comprises a plurality of second facets 23.

The illumination optical unit 4 thus forms a double-faceted system. This basic principle is also referred to as a fly's eye integrator. The individual first facets 21 are imaged into the object field 5 with the aid of the second facet mirror 22. The second facet mirror 22 is the last beam-shaping mirror or else indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are similarly possible. The penultimate mirror M5 and the last mirror M6 each have a through opening for the illumination radiation 16. The projection system 10 is a doubly obscured optical unit. The projection optical unit 10 has an image-side numerical aperture that is greater than 0.4 or 0.5 and may also be greater than 0.6, and may, for example, be 0.7 or 0.75.

Just like the mirrors of the illumination optical unit 4, the mirrors Mi may have a highly reflective coating for the illumination radiation 16.

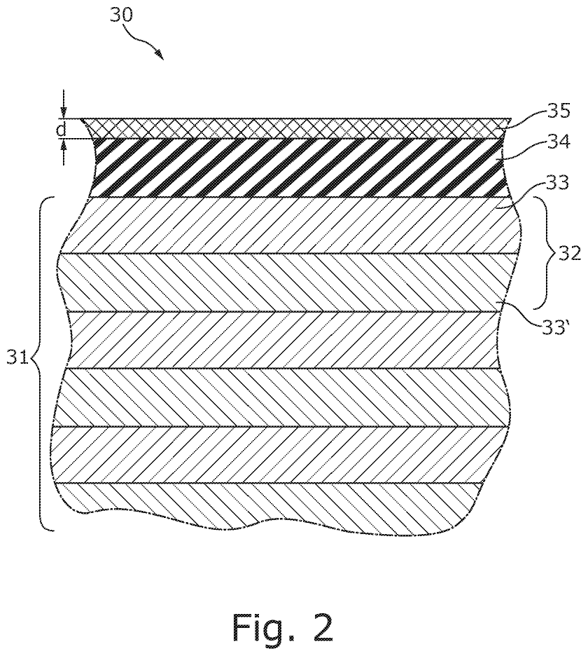

FIG. 2 shows a cross section through the uppermost layers of a reflective optical element 30 for reflection of radiation in the EUV wavelength range. The reflective optical element 30 shown is a mirror, but it may also be another reflective optical element, for example a photomask.

For reflection of radiation in the EUV wavelength range, the reflective optical element 30 has a reflective coating 31 applied to a substrate, not shown in FIG. 2, in the form of a layer stack. The layer stack comprises typically between 50 and 100 double layers 32, where each double layer 32 comprises a first layer 33 consisting of a first layer material and a second layer 33′ consisting of a second layer material. In the case shown, the first layer material is silicon, while the second layer material is molybdenum, but it is also possible to use other materials as layer materials. The reflection of the EUV radiation in the illustrated case of a reflective coating 31 in the form of a layer stack is based on interference effects. As an alternative, the reflective coating 31 may also have only a few layers and may serve to reflect EUV radiation on grazing incidence.

The reflective optical element 30 also has a protective layer 34 that consists at least partly of ruthenium, has been deposited by sputtering and serves to protect the reflective coating 31, especially from oxidation. Alternatively, the protective layer 34 may also consist of another precious metal or another metal or oxide, nitride or boride thereof. The protective layer 34 may also be deposited using a method other than sputtering. The reflective optical element 30 also need not necessarily have a protective layer 34.

An outer layer 35 has been deposited on the protective layer 34, where the deposition has been effected in at least one macro cycle comprising: at least partly depositing the outer layer 35 through an atomic layer deposition (ALD) process in at least one ALD cycle and partly back-etching the outer layer 35. The combination of atomic layer deposition and partial back-etching in one or more macro cycles leads to a robust method of depositing thin and simultaneously continuous layers. The continuous outer layer 35 prevents or reduces damage to the reflective coating 31 and the protective layer 34, especially damage resulting from diffusion of O₂ and H₂. The outer layer 35 shown in FIG. 2, on conclusion of the method, has a final thickness d of about 2 nm. The final thickness d of the outer layer 35 may alternatively be less than 4 nm, less than 2 nm and especially advantageously between 2 nm and 1 nm. As a result of the low final thickness d, the outer layer 35 leads only to a small loss of reflectivity. The protective layer 34 shown has a greater thickness than the outer layer 35. Alternatively, the protective layer 34 may also be thinner than the outer layer 35. The outer layer 35 shown consists at least partly of SiO₂, but it may also consist at least partly of another oxide, for example of TiOₓ or ZrO₂, or another material, for example a laminate or a mixture of oxides.

Alternatively or additionally to the deposition of an outer layer 35, protection of the reflective optical element 30, including avoidance of detachment of the protective layer 34, especially as a result of oxidation of the first layer 33 of the first double layer 32 beneath, may also be accomplished using one or more tie layers (not shown here). A disadvantage of such a solution is that such tie layers typically lead to additional absorption of EUV radiation and hence to losses of reflectivity.

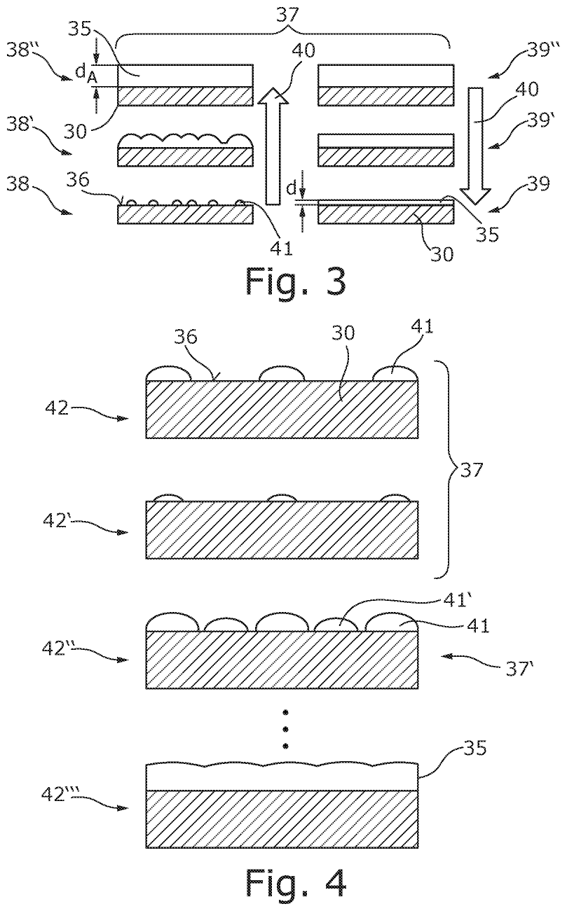

FIG. 3 and FIG. 4 show the deposition of an outer layer 35 on a surface 36 of a reflective optical element 30 for the EUV wavelength range in at least one macro cycle 37. What is shown in each case is a cross section through the outer layer 35 and the uppermost regions of the reflective optical element 30. A protective layer 34 possibly deposited beforehand and the reflective coating 31 of the reflective optical element 30 are not shown here for the sake of simplicity.

In FIG. 3, deposition is effected in a single macro cycle 37. First of all, as shown on the left in FIG. 3, the outer layer 35 is deposited by atomic layer deposition, where the thickness d_{A} of the layer deposited first is greater than the final thickness d. Subsequently, as shown on the right in FIG. 3, the outer layer 35 is back-etched to the final thickness d.

What are shown are respectively three snapshots, at the start 38, in the middle 38′ and after conclusion 38″ of the atomic layer deposition, and at the start 39, in the middle 39′ and after conclusion 39″ of the back-etching. The passing of time is indicated by two arrows 40.

During the atomic layer deposition, growth nuclei are first formed at the start 38, which give rise to individual islands 41. The islands 41 continue to grow until, as shown in the second snapshot 38′, they ultimately merge. After conclusion 38″ of the atomic layer deposition, there is a continuous outer layer 35 having a comparatively high preliminary thickness d_{A}.

During the back-etching, the outer layer 35 is gradually removed. On conclusion 39″ of the back-etching, there is an outer layer 35 which is continuous and comparatively smooth and, and nonetheless has a lower final thickness d than the preliminary thickness d_{A}.

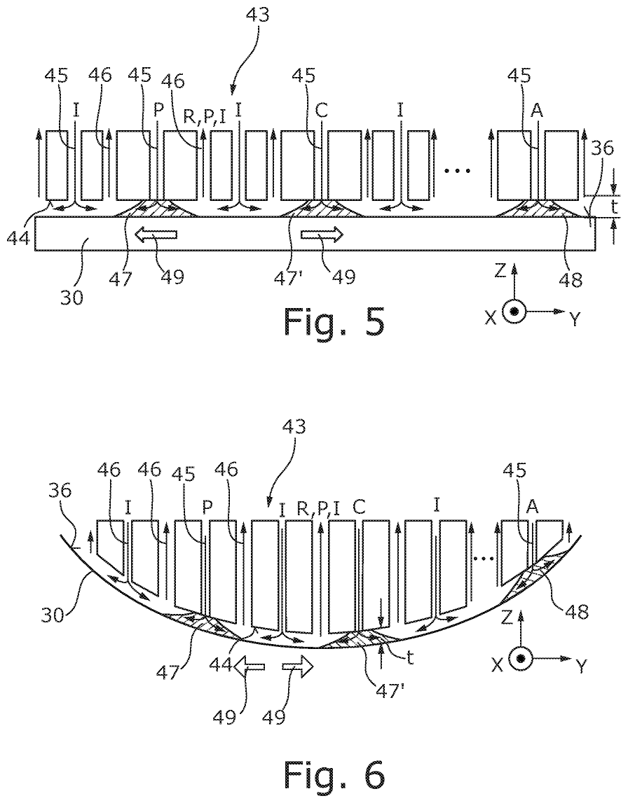

FIG. 4, which is described hereinafter, is informed by FIG. 5 of the article “Prospects for Thermal Atomic Layer Etching Using Sequential, Self-Limiting Fluorination and Ligand-Exchange Reactions” by S. George and Y. Lee, ACS Nano 10, 4889 (2016). In the diagram of FIG. 4, the deposition is effected in more than one macro cycle 37. A total of four snapshots 42, 42′, 42″, 42′″ are shown: A first snapshot 42 after the ALD step of the first macro cycle 37, a second snapshot 42′ after the back-etching in the first macro cycle 37, a third snapshot 42″ after the ALD step of the second macro cycle 37′, and a fourth snapshot 42′″ after a large number of macro cycles 37, 37′, . . . .

In the ALD step of the first macro cycle 37, growth nuclei are first formed, and proceeding from that a few islands 41. These, as shown in the second snapshot 42′, are subsequently partly back-etched. During the ALD step of the second macro cycle 37′, new growth nuclei are now formed in random distribution, and these give rise to new islands 41′. In addition, the islands 41 that remain after the back-etching grow again. Finally, as shown in the fourth snapshot 42′″, after a multitude of macro cycles 37, 37′, . . . , a continuous and simultaneously thin outer layer 35 is formed.

FIG. 5 and FIG. 6 show a cross section of a processing head 43 that operates to deposit an outer layer 35 on a reflective optical element 30 for the EUV wavelength range using the method as described in connection with FIG. 3 and FIG. 4. For ease of description, FIG. 5 and FIG. 6 show Cartesian coordinate systems x, y, z.

The processing head 43 has a processing surface 44, with feed channels 45 and drain channels 46. Through the feed channels 45, process media P, C, A and inert gas I are fed to the processing surface 44. With the drain channels 46, reaction products R, process media P, C, A, and inert gas I are drained from the processing surface 44. The outer layer 35 (not shown in FIG. 5 and FIG. 6) which is deposited with the processing head 43 consists at least partly of SiO₂, but it may also consist at least partly of another oxide or another material. The process media are an Si precursor P in the form of SiCl₄, a coreactant C in the form of an O₂ plasma, and an etching gas A in the form of a mixture of CF₄ and N₂. But it is also possible to use other precursors P, coreactants C, for example H₂O and/or H₂O₂, and etching gases A. The inert gas I is Ar, but it may also be another inert gas I, for example N₂.

Two ALD regions 47, 47′ and one etching region 48 are provided along the processing surface 44. The ALD regions 47, 47′ are separated from one another by the inert gas I in order to prevent any reaction of precursor P and coreactant C in the gas phase. In addition, the ALD regions 47, 47′ are separated from the etching region 48 by the inert gas I. The first component reaction, i.e. the reaction with the precursor P, takes place in the first ALD region 47, while the second component reaction, i.e. the reaction with the coreactant C, takes place in the second ALD region 47′. In a departure from the diagram, it is also possible to provide more than two ALD regions 47, 47′ and/or more than one etching region 48. If two or more etching regions 48 are provided, the partial back-etching can also be effected using a spatial atomic layer etching process. In the case of multiple etching regions 48, these are in each case also spatially separated from one another, as is the case for the ALD regions 47, 47′.

The at least partial deposition by atomic layer deposition and the partial back-etching are effected using a relative movement 49 between the processing head 43 and the reflective optical element 30 and hence between the ALD regions 47, 47′ and the etching region 48 on the one hand and the reflective optical element 30 on the other hand, as a result of which at least subregions of the surface 36 of the reflective optical element 30 to be coated are exposed successively to the first ALD region 47, the second ALD region 47′ and the at least one etching region 48. The distance t between the processing surface 44 and the surface 36 of the reflective optical element 30 is between 20 μm and 100 μm. The depositing using the processing head 43 is effected at atmospheric pressure, but can also be effected under other conditions.

For the deposition of the outer layer 35, the reflective optical element 30 is mounted on a substrate holder (not shown here). The relative movement between the processing head 43 and the reflective optical element 30 is achieved via a movement of the substrate holder. The substrate holder may be of about the same size as the reflective optical element 30. For example, the substrate holder may have a size of 1 m×1 m. Optionally, the substrate holder may be heated and/or cooled. Alternatively or additionally, the feed channels 45 and/or inlets (not shown here) to the feed channels 45 may also be heated or cooled. The feed and drain channels 45, 46, in the example shown, are arranged parallel to the x axis and have a length in x direction of somewhat more than 1 m, in order to cover the whole of the reflective optical element 30. Along the y axis, the feed and drain channels 45, 46 are arranged at a spatial separation. In a departure from the diagram in FIG. 5 and FIG. 6, the feed channels 45, for supply of the process media P, C, A, can have a greater distance t along the z axis, for example of about 100 μm (or less), from the surface 36 of the reflective optical element 30 than the feed channels 45 for supply of inert gas I. This serves for better separation of the process media P, C, A.

At least one of the feed channels 45 may also have a plasma source based on a dielectric barrier discharge (not shown here), which may serve for surface treatment or provide free radicals, for example O, H and/or N radicals, for the at least partial deposition or partial back-etching. A suitable plasma source is described, for example, in US 2017/0137939 A1. The overall apparatus including the processing head 43, the reflective optical element 30 and optionally the substrate holder may also be disposed within an inert gas environment, for example within a glovebox. It is also possible to conduct the method as an in situ method within an EUV lithography system, for example within the projection exposure apparatus 1 shown in FIG. 1, without taking the reflective optical element 30 out of the EUV lithography system.

As an alternative to the use of a processing head 43, the depositing may also be effected with a reactor having multiple reaction chambers, in which case at least one of the reaction chambers serves as at least one ALD region 47, 47′ and at least one further reaction chamber as at least one etching region 48. There may also be a difference in pressure between the reaction chambers.

In a departure from the example shown in FIG. 5, the surface 36 of the reflective optical element 30 shown in FIG. 6 is curved. The processing surface 44 of the processing head 43 shown in FIG. 6 has a shape corresponding approximately to the shape of the curved surface 36 of the reflective optical element 30. The distance t between the processing surface 44 and the curved surface 36 is between 20 μm and 100 μm. In order to achieve the relative movement 49 between the processing head 43 and the reflective optical element 30, the reflective optical element 30 may be moved, as shown in FIG. 6; in general, the reflective optical element 30 and/or the processing head 43, however, is rotated about an axis of rotation not shown in the image.

The curved surface 36 shown in FIG. 6 may, for example, be the surface of the collector mirror 17 shown in FIG. 1. In the collector mirror 17, but also in other reflective optical elements for the EUV wavelength range, rather than the deposition of the outer layer 35 on the whole surface 36, it is possible to repair damaged subregions of the surface 36 where the outer layer 35 has been wholly or partly removed. In this case, the outer layer 35 is deposited solely in the damaged subregion(s) of the surface 36. The damaged subregion(s) in the case of the collector mirror 17 may, for example, be mirror segments. The damaged subregions of the outer layer 35 may be identified with the aid of a suitable metrology method, for example by an EUV radiometry method.

What is claimed is:

1. A method of depositing an outer layer on a surface of a reflective optical element for the extreme ultraviolet (EUV) wavelength range, wherein the depositing is effected in at least one macro cycle comprising:
at least partly depositing the outer layer with an atomic layer deposition (ALD) process in at least one ALD cycle and
partly back-etching the outer layer, wherein said back-etching is conducted with a dry etching process.

2. The method as claimed in claim 1, wherein a final thickness (d) of the outer layer is less than 4 nm.

3. The method as claimed in claim 2, wherein the final thickness (d) of the outer layer is less than 1 nm.

4. The method as claimed in claim 1, wherein the surface of the reflective optical element has a protective layer on which the outer layer is deposited.

5. The method as claimed in claim 4, wherein the protective layer consists at least partly of a precious metal.

6. The method as claimed in claim 1, wherein the macro cycles number 2 or more.

7. The method as claimed in claim 6, wherein the macro cycles number 10 or more.

8. The method as claimed in claim 1, wherein the ALD cycles per macro cycle number between 1 and 100.

9. The method as claimed in claim 8, wherein the ALD cycles per macro cycle number between 10 and 100.

10. The method as claimed in claim 1, wherein the outer layer consists at least partly of at least one oxide.

11. The method as claimed in claim 10, wherein the at least one oxide is selected from the group consisting essentially of: SiO₂, TiOₓ and ZrO₂.

12. The method as claimed in claim 1, wherein said back-etching is conducted with a reactive ion etching process and/or with an atomic layer etching process.

13. The method as claimed in claim 1, wherein said at least partly depositing of the outer layer is effected with the atomic layer deposition process in at least one ALD region and said partly back-etching is effected in at least one etching region spatially separated from the at least one ALD region.

14. The method as claimed in claim 13, wherein the atomic layer etching process is conducted as a spatial atomic layer etching process.

15. The method as claimed in claim 13, wherein the atomic layer deposition process is conducted as a spatial atomic layer deposition process.

16. The method as claimed in claim 15, wherein said depositing is effected with a processing head having
a processing surface and
feed channels with which process media (P, C, A) and inert gas (I) are fed to the processing surface, and
drain channels with which reaction products (R), the process media (P, C, A) and the inert gas (I) are drained from the processing surface, where the ALD regions and the at least one etching region are provided spatially separately along the processing surface with the inert gas (I).

17. The method as claimed in claim 16, wherein said partly back-etching is effected with a plasma source based on a dielectric barrier discharge.

18. The method as claimed in claim 16, wherein the surface of the reflective optical element is curved and the processing surface of the processing head has a shape matched to the curved surface of the reflective optical element.

19. The method as claimed in claim 1, wherein said depositing of the outer layer is effected on a subregion of the surface of the reflective optical element.

20. A reflective optical element for the EUV wavelength range, wherein the reflective optical element has a surface having an outer layer, where the outer layer is deposited by a method as claimed in claim 1.

21. An EUV lithography system comprising at least one reflective optical element as claimed in claim 20.
